(19) United States
(12) Patent Application Publication
(10) Pub. No.: US 2024/0321738 A1
(43) Pub. Date: Sep. 26, 2024

(54) BRIDGING CONTACT STRUCTURES

(71) Applicant: Intel Corporation, Santa Clara, CA (US)

(72) Inventors: Leonard P. Guler, Hillsboro, OR (US); Prabhjot Kaur Luthra, Portland, OR (US); Nidhi Khandelwal, Portland, OR (US); Marie T. Conte, Hillsboro, OR (US); Saurabh Acharya, Hillsboro, OR (US); Shengsi Liu, Portland, OR (US); Gary Allen, Portland, OR (US); Clifford J. Engel, Hillsboro, OR (US); Charles H. Wallace, Portland, OR (US)

(73) Assignee: Intel Corporation, Santa Clara, CA (US)

(21) Appl. No.: 18/125,455

(22) Filed: Mar. 23, 2023

(51) Int. Cl. H01L 23/528; H01L 27/092; H01L 29/06; H01L 29/423; H01L 29/66; H01L 29/778

(52) U.S. Cl. CPC H01L 23/5283; H01L 27/092; H01L 29/0665; H01L 29/42392; H01L 29/66545; H01L 29/778

(57) ABSTRACT

Techniques to form an integrated circuit having a bridging contact structure. A bridging contact structure may, for example, bridge between source/drain contacts and to an adjacent gate electrode within the same device layer. In an example, a gate cut structure extends in a first direction to separate the source or drain regions and gate structures of neighboring semiconductor devices. Contacts may be formed over the source or drain regions of the neighboring devices on opposite sides of the gate cut along a second direction orthogonal to the first direction. A portion of the gate cut is replaced with a first conductive bridge between the source or drain contacts. A portion of one or more dielectric barriers between one of the source or drain contacts and an adjacent gate electrode is replaced with a second conductive bridge in the first direction between the source or drain contact and the gate structure.

### FIELD OF THE DISCLOSURE

The present disclosure relates to integrated circuits, and more particularly, to contact structures.

### BACKGROUND

As integrated circuits continue to scale downward in size, a number of challenges arise. For instance, reducing the size of memory and logic cells within the interconnect structure is becoming increasingly more difficult, as is reducing device spacing at the device layer. Certain aspects of lithography technology can impose physical limits on how accurately certain structures can be aligned. Due to the high complexity of integrated circuit layouts, any structures that require additional masking processes or tight alignment tolerances give rise to reduced yield, or possible points of failure for the device. Accordingly, there remain a number of non-trivial challenges with respect to forming such high-density semiconductor devices.

### BRIEF DESCRIPTION OF THE DRAWINGS

FIG. 1A is an isometric view of an integrated circuit structure that includes a bridging contact structure that includes a first portion that bridges a gate cut and a second portion that bridges a source or drain contact to an adjacent gate electrode, in accordance with an embodiment of the present disclosure.

FIGS. 1B and 1C are different cross-sectional views of the integrated circuit of FIG. 1A that show the contact structure bridging to an adjacent gate electrode (1B), and bridging between adjacent source or drain contacts (1C), in accordance with an embodiment of the present disclosure.

FIGS. 2A and 2B are cross-sectional views that illustrate one stage in an example process for forming an integrated circuit configured with a bridging contact structure such as shown in FIGS. 1A-C, in accordance with an embodiment of the present disclosure.

FIGS. 3A and 3B are cross-sectional views that illustrate another stage in the example process for forming an integrated circuit configured with a bridging contact structure such as shown in FIGS. 1A-C, in accordance with an embodiment of the present disclosure.

FIGS. 4A and 4B are cross-sectional views that illustrate another stage in the example process for forming an integrated circuit configured with a bridging contact structure such as shown in FIGS. 1A-C, in accordance with an embodiment of the present disclosure.

FIGS. 5A and 5B are cross-sectional views that illustrate another stage in the example process for forming an integrated circuit configured with a bridging contact structure such as shown in FIGS. 1A-C, in accordance with an embodiment of the present disclosure.

FIGS. 6A and 6B are cross-sectional views that illustrate another stage in the example process for forming an integrated circuit configured with a bridging contact structure such as shown in FIGS. 1A-C, in accordance with an embodiment of the present disclosure.

FIGS. 7A and 7B are cross-sectional views that illustrate another stage in the example process for forming an integrated circuit configured with a bridging contact structure such as shown in FIGS. 1A-C, in accordance with an embodiment of the present disclosure.

FIGS. 8A and 8B are cross-sectional views that illustrate another stage in the example process for forming an integrated circuit configured with a bridging contact structure such as shown in FIGS. 1A-C, in accordance with an embodiment of the present disclosure.

FIGS. 9A and 9B are cross-sectional views that illustrate another stage in the example process for forming an integrated circuit configured with a bridging contact structure such as shown in FIGS. 1A-C, in accordance with an embodiment of the present disclosure.

FIGS. 10A and 10B are cross-sectional views that illustrate another stage in the example process for forming an integrated circuit configured with a bridging contact structure such as shown in FIGS. 1A-C, in accordance with an embodiment of the present disclosure.

FIGS. 11A and 11B are cross-sectional views that illustrate another stage in the example process for forming an integrated circuit configured with a bridging contact structure such as shown in FIGS. 1A-C, in accordance with an embodiment of the present disclosure.

FIGS. 12A and 12B are cross-sectional views that illustrate another stage in the example process for forming an integrated circuit configured with a bridging contact structure such as shown in FIGS. 1A-C, in accordance with an embodiment of the present disclosure.

FIGS. 13A and 13B are cross-sectional views that illustrate another stage in the example process for forming an integrated circuit configured with a bridging contact structure such as shown in FIGS. 1A-C, in accordance with an embodiment of the present disclosure.

FIG. 14 illustrates a cross-sectional view of a chip package containing one or more semiconductor dies, in accordance with some embodiments of the present disclosure.

FIG. 15 is a flowchart of a fabrication process for a semiconductor device having a bridging contact structure such as shown in FIGS. 1A-C, in accordance with an embodiment of the present disclosure.

FIG. 16 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form an integrated circuit having bridging contact structures. In an example, the contact structures bridge between neighboring source or drain contacts and to an adjacent gate electrode within the same device layer. The techniques can be used in any number of integrated circuit applications and are particularly useful with respect to logic and memory cells, such as those cells that use finFETs or gate-all-around transistors (e.g., ribbonFETs and nanowire FETs). In one such example, neighboring semiconductor devices each include a semiconductor region extending (e.g., in a first direction) from opposite sides of a shared source or drain region, with a separate gate structure extending (e.g., in a second direction perpendicular to the first direction) over each of the semiconductor regions of the neighboring semiconductor devices. A gate cut interrupts at least one of the gate structures so as to isolate the gate electrode of one semiconductor device from the gate electrode of a neighboring semiconductor device. According to some such embodiments, the gate cut structure further extends in the first direction so as to isolate the source or drain region of one semiconductor device from the source or drain region of a neighboring semiconductor device. Contacts may be formed over the source or drain regions of the neighboring devices on opposite sides of the gate cut along the second direction. According to some such examples, a portion of the gate cut is removed to form a first conductive bridge that extends in the second direction between the neighboring source or drain contacts. A portion of one or more dielectric barriers between one of the source or drain contacts and an adjacent gate electrode may also be removed to form a second conductive bridge that extends in the first direction between the source or drain contact and the gate structure. Together, the contacts and the conductive bridges combine to form a bridging contact structure that contacts at least two source or drain regions and at least one of the gate electrodes. Numerous variations and embodiments will be apparent in light of this disclosure.

### General Overview

As previously noted above, there remain a number of non-trivial challenges with respect to integrated circuit fabrication. In more detail, gate cuts are sometimes provided between adjacent semiconductor devices to isolate first and second portions of a gate structure that crosses over each of the adjacent semiconductor devices. Accordingly, a gate cut can be used to isolate the gates of two devices from one another. Such gate cuts may also extend to isolate adjacent source or drain regions and their associated conductive contacts from each other. The source or drain contacts are typically separated from gate structures using one or more dielectric spacer structures. With all conductive features isolated between devices, interconnects between devices are often performed within one or more interconnect levels formed above the devices during backend processing (sometimes called back end of line or BEOL processing. However, with circuits becoming more complex and the device density increasing, making these interconnects during BEOL processing becomes increasingly challenging.

Thus, and in accordance with an embodiment of the present disclosure, techniques are provided herein to form one or more bridging contact structures in the device layer where source and drain contacts and gate electrodes are formed. In an example, a bridging contact structure bridges between neighboring source or drain contacts and also to an adjacent gate electrode effectively within the same contact layer of the device. Such bridging contacts can be formed within the device layer and free up space within any higher interconnect layers. According to some such examples, a contact may include a first section over a first source or drain region, a second section over a second adjacent source or drain region, a first bridge connected between the first section and the second section, and a second bridge extending off of the first section and connected to a gate electrode adjacent to the first section. Each of the various contact sections and bridges may be formed from the same conductive material or from different conductive materials. The first bridge may extend across a gate cut running between the first source or drain region and the second source or drain region. The second bridge may extend orthogonally from the first contact section to contact the adjacent gate electrode. According to some such embodiments, any number of first bridge segments may be formed to link between any number source/drain contacts along a common source/drain trench.

According to an embodiment, an integrated circuit includes a first semiconductor device having a first semiconductor region extending in a first direction from a first source or drain region, and a first gate structure extending in a second direction over the first semiconductor region, a second semiconductor device having a second semiconductor region extending in the first direction from a second source or drain region, and a second gate structure extending in the second direction over the second semiconductor region, a dielectric wall extending in the first direction between the first gate structure and the second gate structure and between the first source or drain region and the second source or drain region, and a conductive contact having a first region on a top surface of the first source or drain region, a second region that extends through a portion of the dielectric wall along the second direction, a third region on a top surface of the second source or drain region, and a fourth region on a top surface of the first gate structure. Thus, the first source or drain region, the second source or drain region, and the first gate structure are each shorted or otherwise in contact with one another, by a bridging contact structure formed in the device layer. One or more interconnect layers may be formed above that device layer and bridging contact structure.

According to another embodiment, an integrated circuit includes a first semiconductor device having a first semiconductor region extending in a first direction from a first source or drain region, and a first gate structure extending in a second direction over the first semiconductor region, a second semiconductor device having a second semiconductor region extending in the first direction from a second source or drain region, and a second gate structure extending in the second direction over the second semiconductor region, a dielectric wall extending in the first direction between the first gate structure and the second gate structure and between the first source or drain region and the second source or drain region, a first conductive structure on a top surface of the first source or drain region, a second conductive structure on a top surface of the second source or drain region, a third conductive structure extending between the first conductive structure and the second conductive structure, and a fourth conductive structure extending from the first conductive structure and on a top surface of the first gate structure. Thus, the first, second, third, and fourth conductive structures form a bridging contact structure in the device layer. One or more interconnect layers may be formed above that device layer and bridging contact structure.

According to another embodiment, a method of forming an integrated circuit includes: forming a first fin comprising first semiconductor material and a second fin comprising second semiconductor material, the first and second fins extending above a substrate and each extending in a first direction; forming a gate electrode extending over the first fin and the second fin in a second direction different from the first direction; forming a dielectric layer over the gate electrode; forming a first source or drain region at one end of the first fin and a second source or drain region at one end of the second fin; forming a recess through the gate electrode between the first fin and the second fin, the recess further extending in the first direction between the first source region and the second source region; forming a dielectric material within the recess; forming a first conductive contact on the first source or drain region and a second conductive contact on the second source or drain region; recessing a portion of the dielectric material between the first conductive contact and the second conductive contact to form a first recess; recessing at least a portion of the dielectric layer to expose at least a portion of the gate electrode and to form a second recess; and forming first conductive material within the first recess and second conductive material within the second recess, such that the first conductive material contacts the first conductive contact and the second conductive contact and the second conductive material contacts the first conductive contact.

The techniques can be used with any type of non-planar transistors, including finFETs (sometimes called double-gate transistors, or tri-gate transistors), or nanowire and nanoribbon transistors (sometimes called gate-all-around transistors), to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of one or more conductive bridges within the device layer that bridge across gate cuts between contacts over source or drain regions and/or across dielectric spacers to bridge between a source/drain contact and an adjacent gate electrode. The bridge sections may have the same conductive material as the conductive contacts on the source or drain regions, or a different conductive material.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element (s) or feature (s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

### Architecture

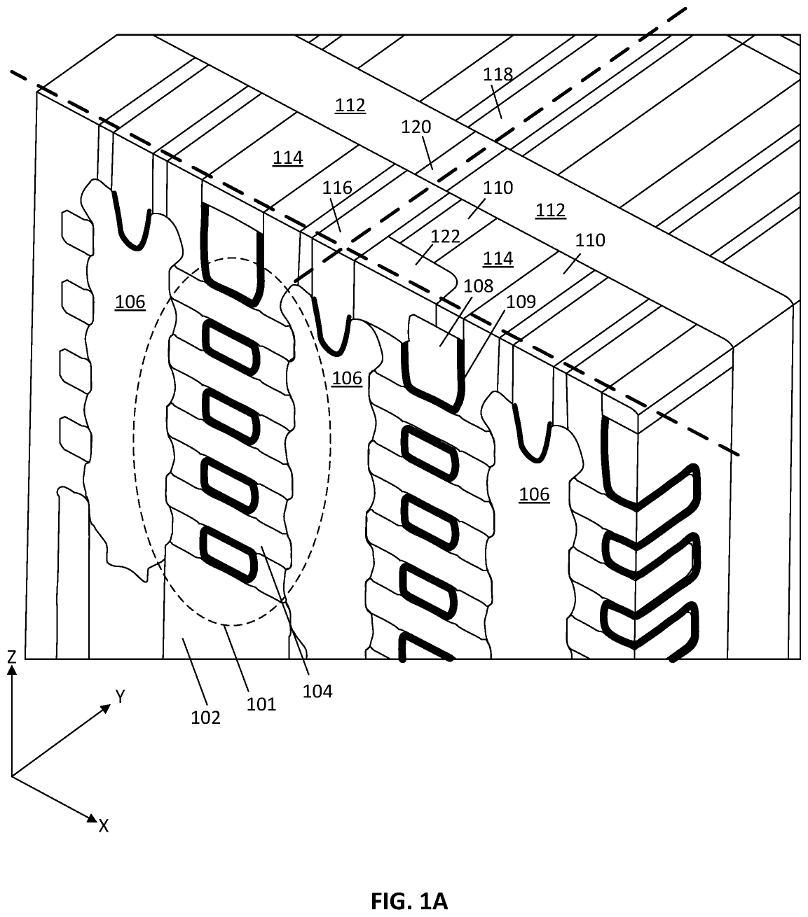

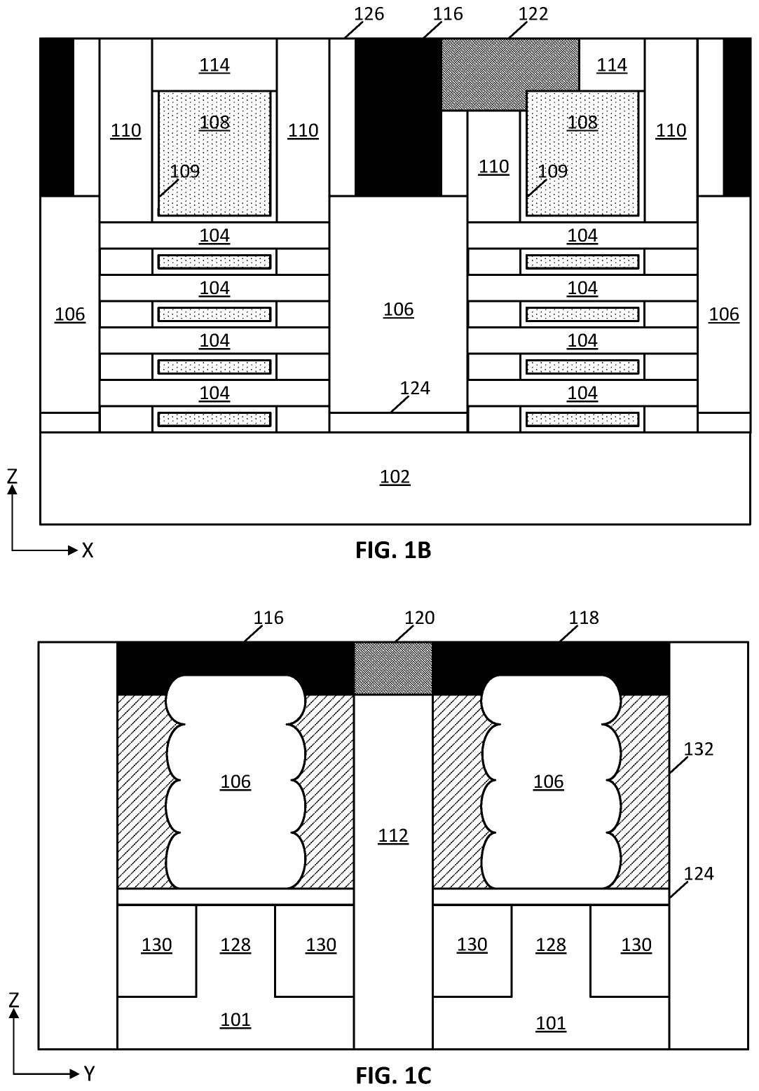

FIG. 1A is an isometric view of a portion of an integrated circuit that includes various semiconductor devices 101, in accordance with an embodiment of the present disclosure. Each of the semiconductor devices may be non-planar metal oxide semiconductor (MOS) transistors, such as tri-gate (e.g., finFET) or gate-all-around (GAA) transistors, although other transistor topologies and types could also benefit from the techniques provided herein. The examples herein illustrate semiconductor devices with a GAA structure (e.g., having nanoribbons, nanowires, or nanosheets that extend between source and drain regions).

The semiconductor material used in each of the semiconductor devices may be formed from a semiconductor substrate 102. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, a lower portion of substrate 102 is removed and replaced with one or more backside interconnect layers to form backside signal and power routing.

The one or more semiconductor regions of the devices may include fins that can be, for example, native to substrate 102 (formed from the substrate itself), such as silicon fins etched from a bulk silicon substrate. Alternatively, the fins can be formed of material deposited onto substrate 102. In one such example case, a blanket layer of silicon germanium (SiGe) can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons during a gate forming process where one type of the alternating layers is selectively etched away so as to liberate the other type of alternating layers within the channel region, so that a gate-all-around process can then be carried out. Again, the alternating layers can be blanket deposited and then etched into fins or deposited into fin-shaped trenches.

Each semiconductor device 101 includes one or more semiconductor regions, such as one or more nanoribbons 104 extending between epitaxial source or drain regions 106 in a first direction along the X-axis. According to some embodiments, semiconductor devices 101 further include a subfin region beneath nanoribbons 104. According to some embodiments, the subfin region is a portion of the corresponding semiconductor fin that remains after formation of the various transistors and may be formed from substrate 102. Accordingly, the subfin region may include the same semiconductor material as substrate 102 (or any semiconductor material in situations where substrate 102 is removed).

A gate structure that includes gate electrode 108 and a gate dielectric 109 extends over the one or more semiconductor regions of a given semiconductor device 101 in a second direction along the Y-axis to form the transistor gate. Gate electrode 108 may represent any number of conductive layers and gate dielectric 109 may represent any number of dielectric layers. Gate electrode 108 may include any sufficiently conductive material such as a metal, metal alloy, or doped polysilicon. In some embodiments, gate electrode 108 includes one or more workfunction metals around the one or more semiconductor regions. In some embodiments, p-channel devices include a workfunction metal having titanium around its one or more semiconductor regions and n-channel devices include a workfunction metal having tungsten around its one or more semiconductor regions. Gate electrode 108 may also include a fill metal or other conductive material around the workfunction metals to provide the whole gate electrode structure. Gate dielectric 109 may include any suitable gate dielectric material(s). In some embodiments, gate dielectric 109 includes a layer of native oxide material (e.g., silicon oxide) on the nanoribbons 104 or other semiconductor regions, and a layer of high-k dielectric material (e.g., hafnium oxide) on the native oxide. According to some embodiments, spacer structures 110 are present along the sidewalls of the gate structures. Spacer structures 110 may be any suitable dielectric material, such as silicon nitride, and provide separation between a given gate structure and the adjacent source or drain region 106. Spacer structures 110 may run along the gate structure sidewalls in the second direction and extend the entire height of the gate structure along the Z-axis.

According to some embodiments, adjacent gate layers 108 may be separated from one another along the second direction (e.g., along the Y-axis) by a dielectric wall 112. Any number of suitable dielectric materials can be used for dielectric wall 112, such as silicon nitride or silicon oxynitride or low-K versions of these (e.g., porous silicon oxynitride). Any number of dielectric walls 12 may run lengthwise parallel to one another along the X-axis and extend along the Z-axis at least through an entire thickness of the gate structures and up to a cap layer 114 on a top surface of gate electrode 108. According to some embodiments, dielectric wall 112 continues to extend along the X-axis between multiple pairs of semiconductor devices and between the source or drain regions 106 of the devices as described in more detail below.

The dielectric cap layer 114 may run lengthwise along the Y-axis along the top surface of gate electrode 108 and be interrupted by dielectric wall 112. Cap layer 114 may include the same dielectric material as dielectric wall 112, in some examples.

According to some embodiments, a first conductive contact 116 is on a corresponding source or drain region 106 while a second conductive contact 118 is on an adjacent source or drain region along the second direction. The two conductive contacts 116/118 may be separated by dielectric wall 112. Each conductive contact 116/118 can include any suitable conductive material, such as tungsten, molybdenum, or other metals. Conductive contacts 116/118 may be formed together such that they include the same conductive material.

According to some embodiments, a first conductive bridge 120 may extend through dielectric wall 112 along the second direction to connect between first conductive contact 116 and second conductive contact 118. First conductive bridge 120 may only extend through a portion of dielectric wall 112 along the Z-axis. In some examples, first conductive bridge 120 has a smaller width along the first direction than either of first conductive contact 116 or second conductive contact 118. First conductive bridge 120 may include any suitable conductive material, such as tungsten, molybdenum, or other metals. In some examples, first conductive bridge 120 includes the same conductive material as first conductive contact 116 and second conductive contact 118.

According to some embodiments, a second conductive bridge 122 extends between first conductive contact 116 and gate electrode 108. Second conductive bridge 122 may extend through a portion of spacer structure 110 and a portion of dielectric cap layer 114. In some examples, second conductive bridge 122 also contacts a portion of source or drain region 106. Second conductive bridge 122 may extend in the first direction between first conductive contact 116 and gate electrode 108. Second conductive bridge 122 may include any suitable conductive material, such as tungsten, molybdenum, or other metals. In some examples, second conductive bridge 122 includes the same conductive material as first conductive contact 116 and gate electrode 108. According to some embodiments, first conductive bridge 120 and second conductive bridge 122 are formed together such that they include the same conductive material. The conductive material of first conductive bridge 120 and second conductive bridge 122 may be different from the conductive material of first conductive contact 116 and second conductive contact 118.

First conductive contact 116, second conductive contact 118, first conductive bridge 120, and second conductive bridge 122 may collectively form a single conductive contact within the device layer that contacts multiple source or drain regions 106 and at least one gate electrode 108. In some embodiments, there may not be any noticeable seams or boundaries between any of first conductive contact 116, second conductive contact 118, first conductive bridge 120, or second conductive bridge 122 depending on the materials used. When different materials or deposition processes are used, seams or boundaries may be noticeable between different conductive elements.

FIG. 1B illustrates a cross-section view across the XZ plane identified by the dashed line along the X-axis in FIG. 1A, according to an embodiment. A dielectric structure 124 may be present beneath source or drain regions 106 to isolate source or drain regions 106 from substrate 102. Dielectric structure 124 may include any number of dielectric layers and/or materials, such as silicon dioxide, silicon nitride, or silicon oxynitride. In some embodiments, first conductive contact 116 is flanked by contact spacers 126 that run along the sidewalls of first conductive contact 116 (e.g., in the second direction). Contact spacers 126 may be similar to spacer structures 110 and may include the same dielectric material or similar dielectric materials. Second conductive bridge 122 can be seen extending from first conductive contact 116 to at least a portion of gate electrode 108. In some examples, second conductive bridge 122 contacts both a top surface of gate electrode 108 and a side surface of gate electrode 108.

FIG. 1C illustrates another cross-section view across the YZ plane identified by the dashed line along the Y-axis in FIG. 1A, according to an embodiment. Any of source or drain regions 106 may act as either a source region or a drain region, depending on the application and dopant profile. Any semiconductor materials suitable for source and drain regions can be used (e.g., group IV and group III-V semiconductor materials) for any of the illustrated source or drains regions 106. In any such cases, the composition and doping of source or drain regions 106 may be the same or different, depending on the polarity of the transistors. For example, any semiconductor devices that are p-type MOS (PMOS) transistors have a high concentration of p-type dopants in the associated source or drain regions 106, and any semiconductor devices that are n-type MOS (NMOS) transistors have a high concentration of n-type dopants in the associated source or drain regions 106. Any number of source and drain configurations and materials can be used. In some embodiments, source or drain regions 106 extend above subfin regions 128. As described above, subfin regions 128 are extensions of substrate 102 created during the formation of semiconductor fins. In some embodiments, subfin regions 128 extend through a dielectric fill 130 that acts as shallow trench isolation (STI) between devices. Dielectric fill 130 can be any suitable dielectric material, such as silicon oxide. Another dielectric fill 132 may be present around portions of source or drain regions 106 within the source/drain trench that extends along the second direction. Dielectric fill 132 may include any suitable dielectric material and may include the same material as dielectric fill 130.

As noted above, dielectric walls 112 extend between adjacent ones of source or drain regions 106. In some examples, dielectric walls 112 extend down through at least a portion of dielectric fill 130 or extend down into a portion of substrate 102 (e.g., through an entire thickness of dielectric fill 130). First conductive bridge 120 extends across a given dielectric wall 112 to connect between first conductive contact 116 and second conductive contact 118. First conductive bridge 120 may extend to any depth through dielectric wall 112.

### Fabrication Methodology

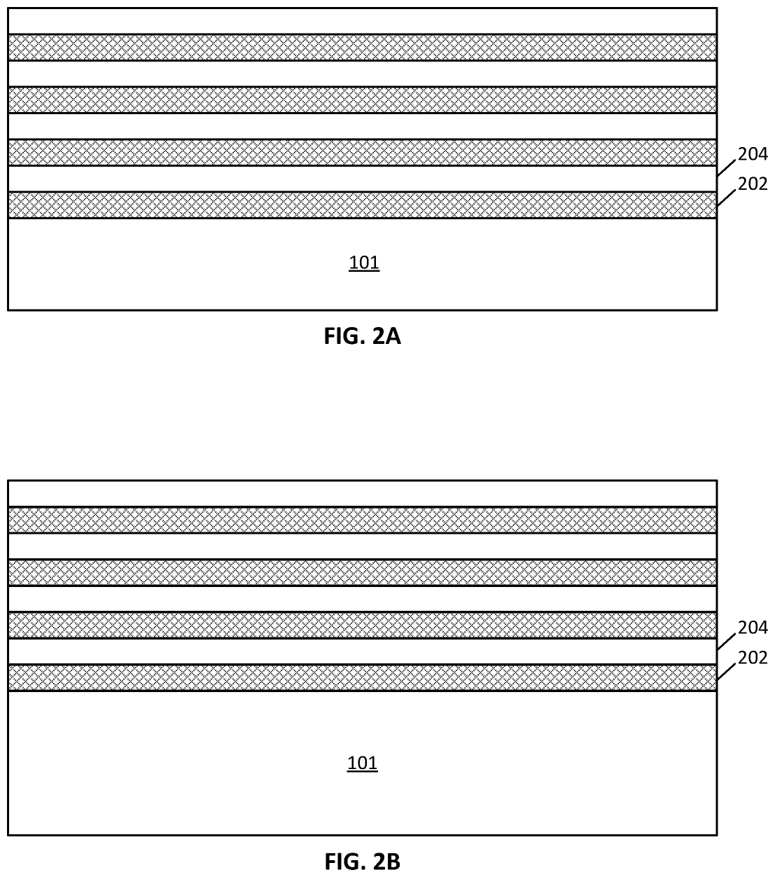

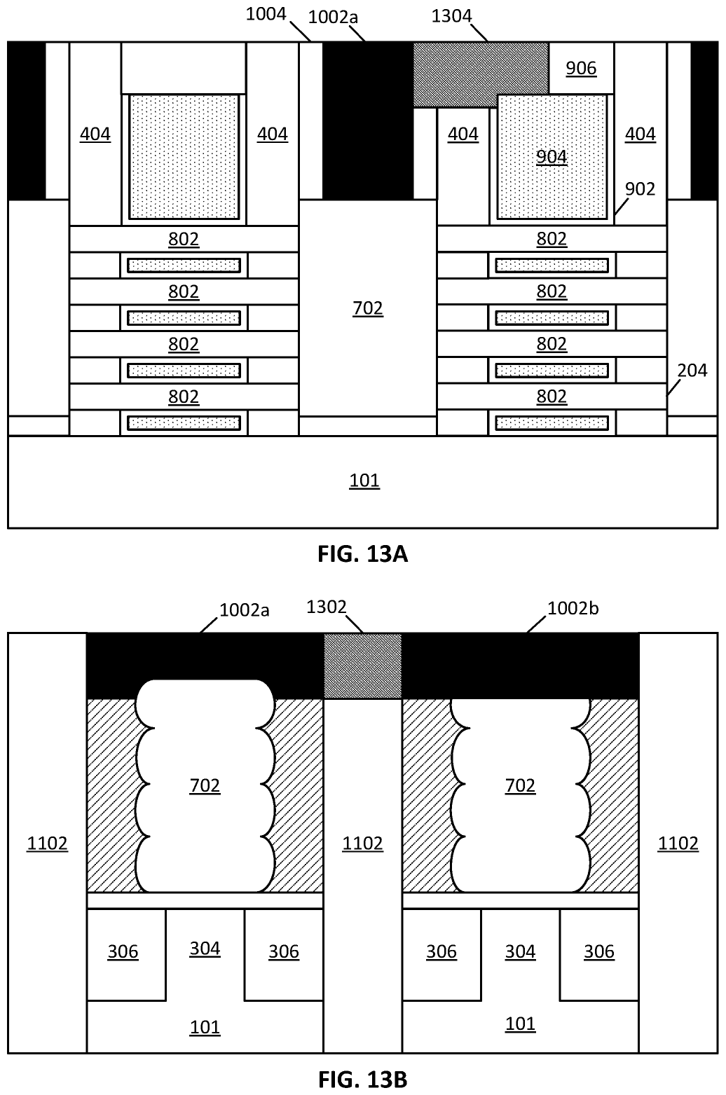

FIGS. 2A-13A and 2B-13B include cross-sectional views that collectively illustrate an example process for forming an integrated circuit configured with a contact structure that bridges between source/drain contacts and to an adjacent gate electrode, in accordance with an embodiment of the present disclosure. FIGS. 2A-13A represent a similar cross-sectional view taken across the XZ plane in FIG. 1A, while FIGS. 2B-13B represent a cross-sectional view taken across the YZ in FIG. 1A. Each set of figures sharing the same letter shows an example structure that results from the process flow up to that point in time, so the depicted structure evolves as the process flow continues, culminating in the structure shown in FIGS. 13A-13B, which is similar to the structure shown in FIGS. 1B and 1C. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIGS. 2A and 2B each illustrates a cross-sectional view taken through a substrate 102 having a series of material layers formed over the substrate, according to an embodiment of the present disclosure. Alternating material layers may be deposited over substrate 102 including sacrificial layers 202 alternating with semiconductor layers 204. The alternating layers are used to form GAA transistor structures. Any number of alternating sacrificial layers 202 and semiconductor layers 204 may be deposited over substrate 102.

According to some embodiments, semiconductor layers 204 have a different material composition than sacrificial layers 202. In some embodiments, semiconductor layers 204 are silicon germanium (SiGe) while sacrificial layers 202 include a semiconductor material suitable for use as a nanoribbon such as silicon (Si), SiGe, germanium, or III-V materials like indium phosphide (InP) or gallium arsenide (GaAs). In examples where SiGe is used in each of semiconductor layers 204 and in sacrificial layers 202, the germanium concentration is different between semiconductor layers 204 and sacrificial layers 202. For example, semiconductor layers 204 may include a higher germanium content compared to sacrificial layers 202. In some examples, sacrificial layers 202 may be doped with either n-type dopants (to produce a p-channel transistor) or p-type dopants (to produce an n-channel transistor).

While dimensions can vary from one example embodiment to the next, the thickness of each semiconductor layer 204 may be between about 5 nm and about 20 nm. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). Each of semiconductor layers 204 and sacrificial layers 202 may be deposited using any known material deposition technique, such as chemical vapor deposition (CVD), plasma-enhanced chemical vapor deposition (PECVD), physical vapor deposition (PVD), or atomic layer deposition (ALD), or epitaxial growth.

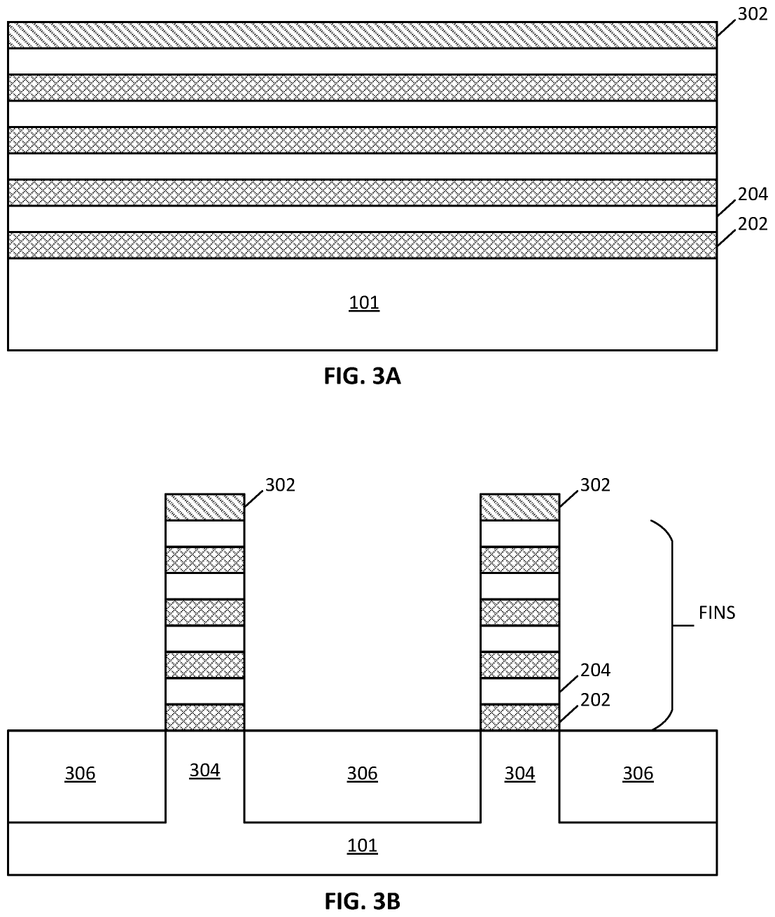

FIGS. 3A and 3B depict the cross-section views of the structure shown in FIGS. 2A and 2B, respectively, following the formation of a cap layer 302 and the subsequent formation of fins beneath cap layer 302, according to an embodiment. Cap layer 302 may be any suitable hard mask material such as a carbon hard mask (CHM) or silicon nitride. Cap layer 302 is patterned into rows to form corresponding rows of fins from the alternating layer stack of sacrificial layers 202 and semiconductor layers 204. Cap layer 302 extends along the top of each fin in a first direction, as seen in FIG. 3A.

According to some embodiments, an anisotropic etching process through the layer stack continues into at least a portion of substrate 102. Portions of substrate 102 beneath the fins are not etched and yield subfin regions 304. The etched portion of substrate 102 may be filled with a dielectric fill 306 that acts as shallow trench isolation (STI) between adjacent fins. Dielectric fill 306 may be any suitable dielectric material such as silicon oxide. Subfin regions 304 represent remaining portions of substrate 102 between dielectric fill 306, according to some embodiments.

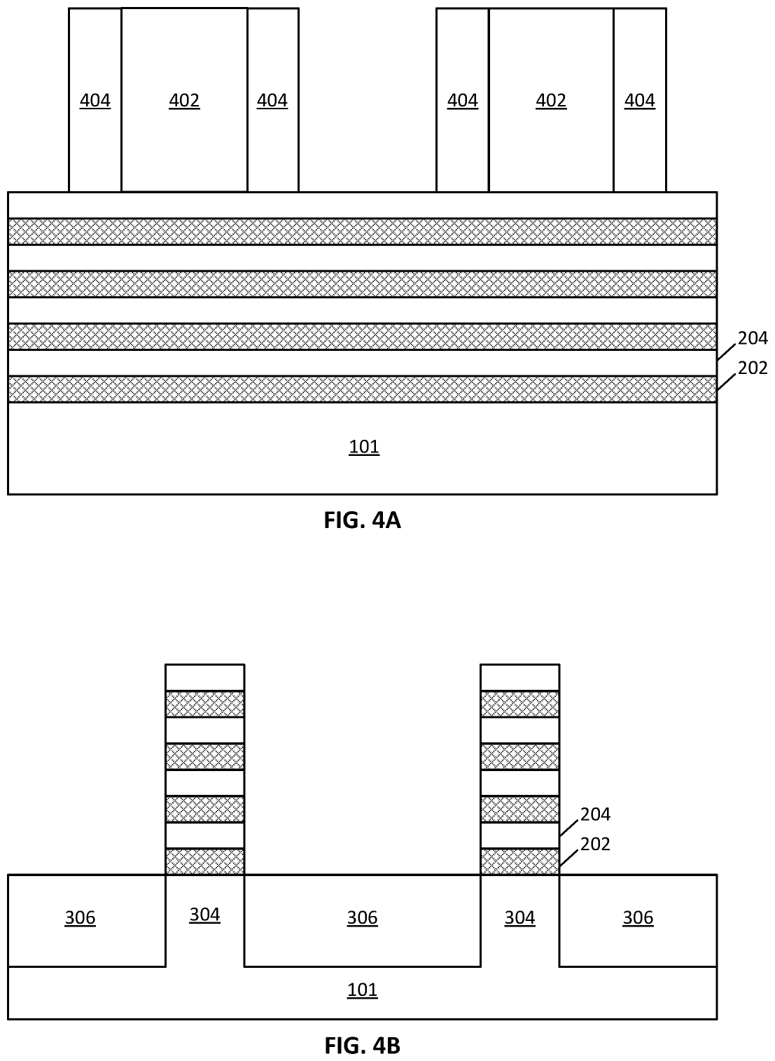

FIGS. 4A and 4B depict cross-section views of the structures shown in FIGS. 3A and 3B following the formation of sacrificial gates 402, according to some embodiments. A gate masking layer may first be patterned in strips that extend orthogonally across each of the fins (e.g., in a second direction) in order to form corresponding sacrificial gates 402 in strips beneath the gate masking layers. Afterwards, the gate masking layers may be removed or may remain as a cap layer above each sacrificial gate 402. According to some embodiments, the sacrificial gate material is removed in all areas not protected by the gate masking layers. Sacrificial gate 402 may be any suitable material that can be selectively removed without damaging the semiconductor material of the fins. In some examples, sacrificial gate 402 includes polysilicon.

According to some embodiments, spacer structures 404 are formed along the sidewalls of sacrificial gates 402. Spacer structures 404 may be deposited and then etched back such that spacer structures 404 remain mostly only on sidewalls of any exposed structures. In the cross-section view of FIG. 4B, spacer structures 404 may also be formed along sidewalls of the exposed fins over dielectric fill 306. Such sidewall spacers on the fins can be removed during later processing when forming the source or drain regions. According to some embodiments, spacer structures 404 may be any suitable dielectric material, such as silicon nitride, silicon carbon nitride, or silicon oxycarbonitride. In one such embodiment, spacer structures 404 comprise a nitride and dielectric fill 306 comprises an oxide, so as to provide a degree of etch selectivity during final gate processing. Other etch selective dielectric schemes (e.g., oxide/carbide, carbide/nitride) can be used as well for spacer structures 404 and dielectric fill 306. In other embodiments, spacer structures 404 and dielectric fill 306 are compositionally the same or otherwise similar, where etch selectivity is not employed.

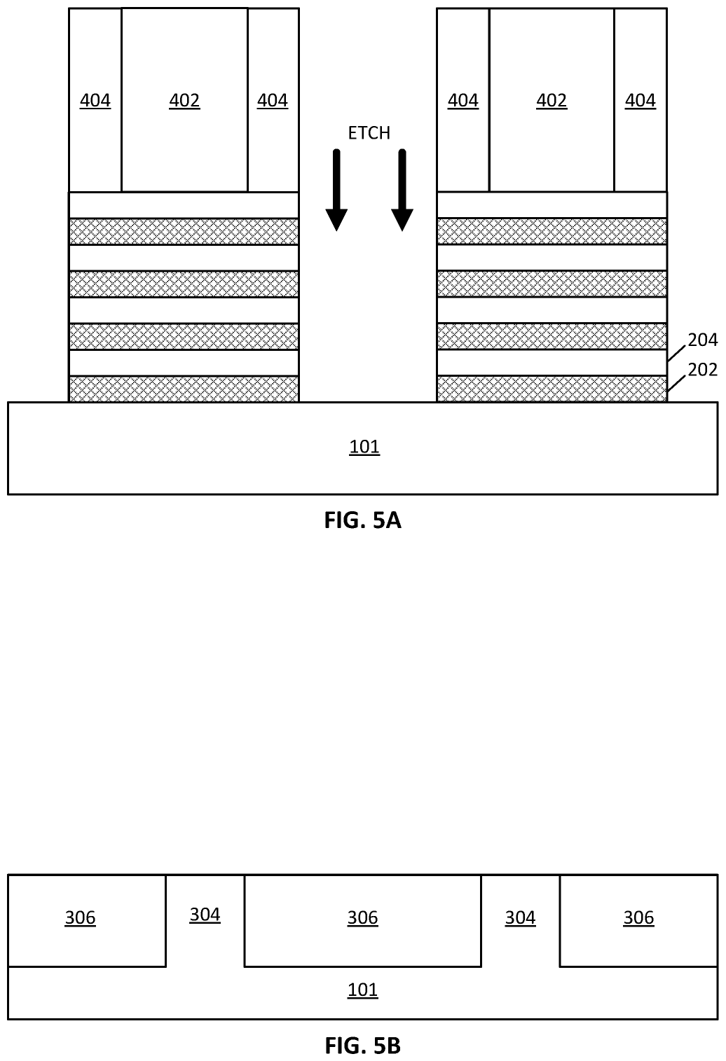

FIGS. 5A and 5B depict cross-section views of the structures shown in FIGS. 4A and 4B following the removal of exposed portions of the fins not protected by sacrificial gates 402 and spacer structures 404, according to some embodiments. The exposed fin portions may be removed using any anisotropic etching process, such as reactive ion etching (RIE). The removal of the exposed fin portions creates source or drain trenches that alternate with gate trenches (currently filled with sacrificial gates 402) along the first direction, according to some embodiments. In some embodiments, at least a portion of subfin regions 304 are also removed such that a top surface of subfin regions 304 is recessed below a top surface of dielectric fill 306. The recessed area above subfin regions 304 may be filled with one or more dielectric materials.

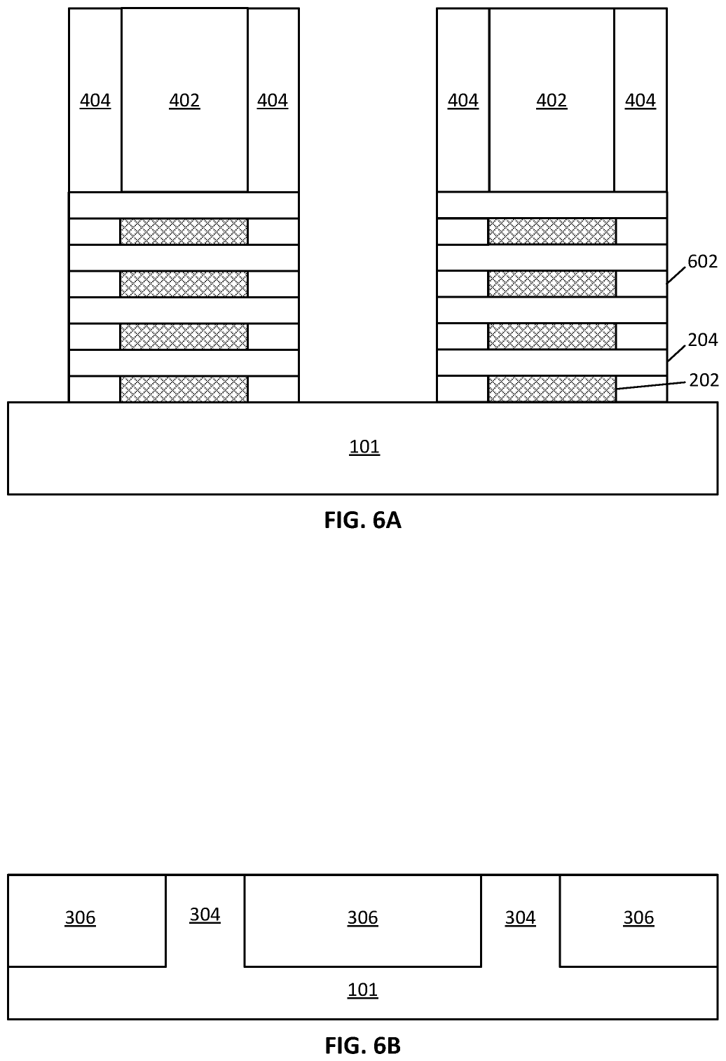

FIGS. 6A and 6B depict cross-section views of the structures shown in FIGS. 5A and 5B following the removal of portions of sacrificial layers 202 and subsequent formation of internal spacers 602, according to an embodiment of the present disclosure. An isotropic etching process may be used to selectively recess the exposed ends of each sacrificial layer 202 (e.g., while etching comparatively little of semiconductor layers 204). Internal spacers 602 may have a material composition that is similar to or the exact same as spacer structures 404. Accordingly, internal spacers 602 may be any suitable dielectric material that exhibits high etch selectively to semiconductor materials such as silicon and/or silicon germanium. Internal spacers 602 may be, for example, conformally deposited over the sides of the fin structure using a conformal deposition process like CVD or ALD and then etched back using an isotropic etching process to expose the ends of semiconductor layers 204. According to some embodiments, internal spacers 602 have a similar width (e.g., along the first direction) to spacer structures 404.

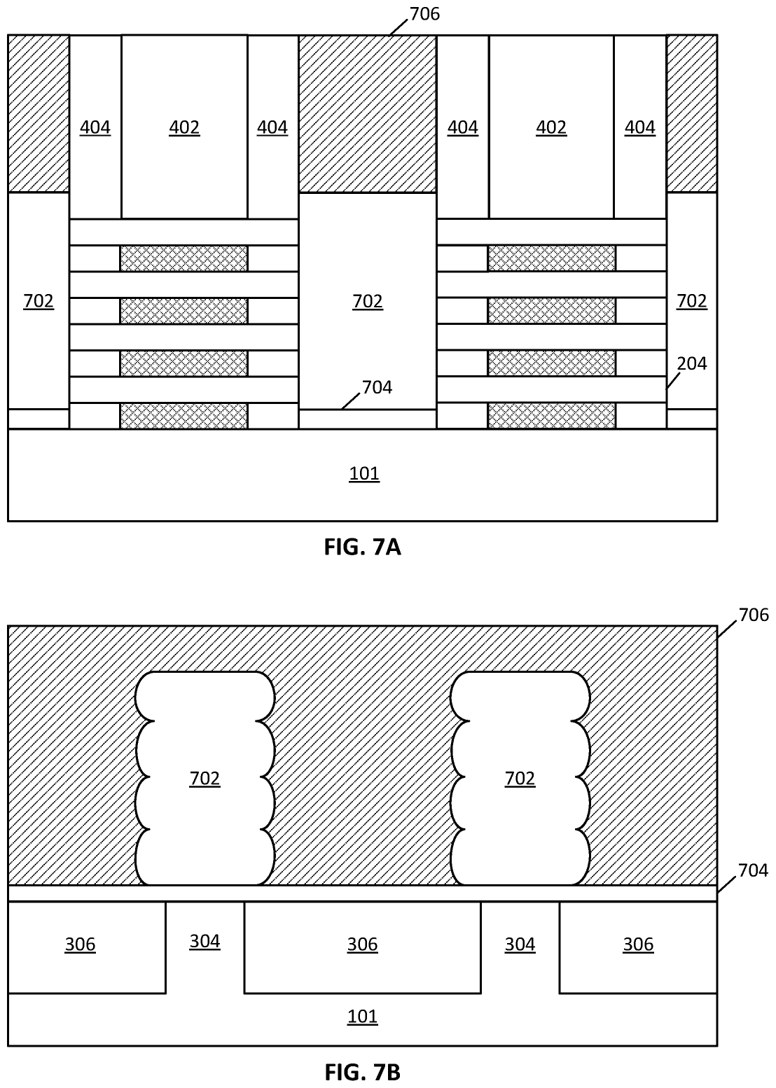

FIGS. 7A and 7B depict cross-section views of the structure shown in FIGS. 6A and 6B, respectively, following the formation of source or drain regions 702 within the source/drain trenches, according to some embodiments. Source or drain regions 702 may be formed in the areas that had been previously occupied by the exposed fins between spacer structures 404. According to some embodiments, source or drain regions 702 are epitaxially grown from the exposed semiconductor material at the ends of semiconductor layers 204. In some example embodiments, source or drain regions 702 are NMOS source or drain regions (e.g., epitaxial silicon) or PMOS source or drain regions (e.g., epitaxial SiGe). In some examples, a bottom dielectric layer 704 is formed within the source/drain trench prior to the formation of source or drain regions 702. Bottom dielectric layer 704 can include any suitable dielectric material, such as silicon dioxide.

According to some embodiments, a dielectric fill 706 is provided between adjacent source or drain regions 702. In some examples, dielectric fill 706 occupies a remaining volume within the source/drain trench around and over source or drain regions 702. Dielectric fill 706 may be any suitable dielectric material, such as silicon dioxide. In some examples, dielectric fill 706 extends up to and planar with a top surface of spacer structures 404 (e.g., following a polishing procedure).

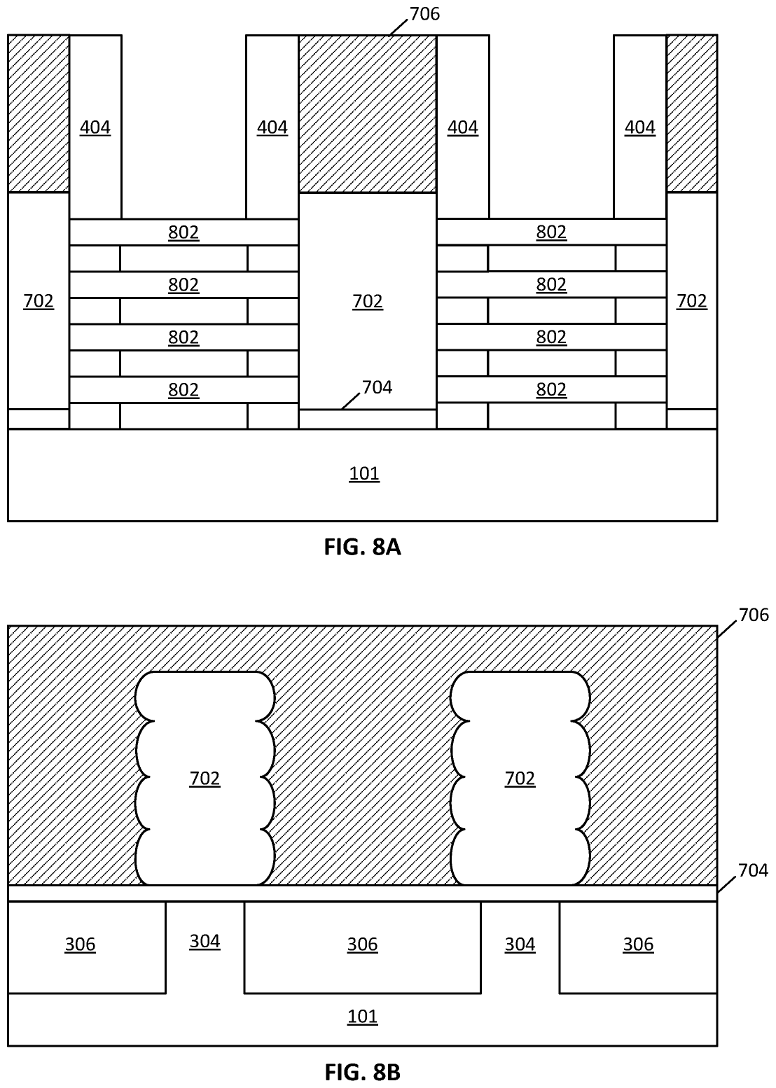

FIGS. 8A and 8B depict cross-section views of the structure shown in FIGS. 7A and 7B, respectively, following the removal of sacrificial gates 402 and sacrificial layers 202, according to some embodiments. In examples where gate masking layers are still present, they would be removed at this time. Once sacrificial gates 402 are removed, the fins extending between spacer structures 404 are exposed.

In the example where the fins include alternating semiconductor layers, sacrificial layers 202 are selectively removed to leave behind nanoribbons 802 that extend between corresponding source or drain regions 702. Each vertical set of nanoribbons 802 represents the semiconductor region of a different semiconductor device. It should be understood that nanoribbons 802 may also be nanowires or nanosheets. Sacrificial gates 402 and sacrificial layers 202 may be removed using the same isotropic etching process or different isotropic etching processes.

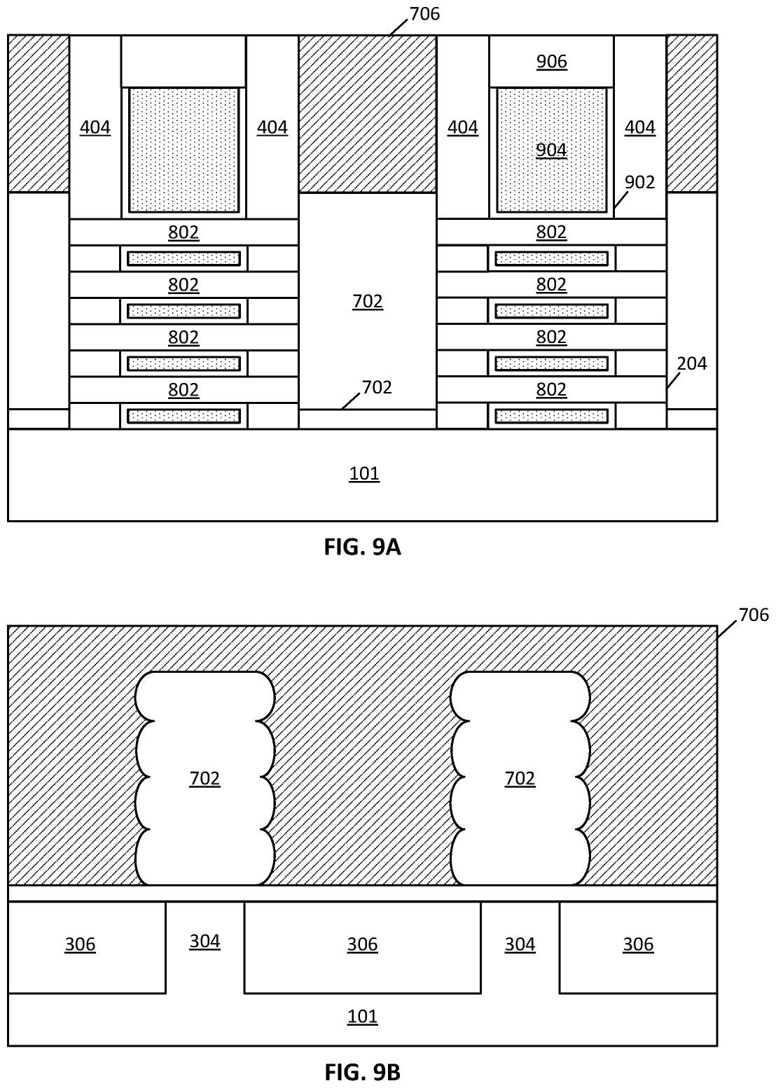

FIGS. 9A and 9B depict cross-section views of the structure shown in FIGS. 8A and 8B, respectively, following the formation of a gate structure, which includes a gate dielectric 902 and a gate electrode 904, and subsequent gate cap 906, according to some embodiments. Gate dielectric 902 may be first formed around nanoribbons 802 prior to the formation of gate electrode 904, which may include one or more conductive layers. Gate dielectric 902 may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 902 includes a layer of hafnium oxide with a thickness between about 1 nm and about 5 nm. In some embodiments, gate dielectric 902 may include one or more silicates (e.g., titanium silicate, tungsten silicate, niobium silicate, and silicates of other transition metals). In some cases, gate dielectric 902 includes a first layer on nanoribbons 802, and a second layer on the first layer. The first layer can be, for instance, an oxide of the semiconductor material of nanoribbons 802 (e.g., silicon dioxide) and the second layer can be a high-k dielectric material (e.g., hafnium oxide).

The one or more conductive layers that make up gate electrode 904 may be deposited using electroplating, electroless plating, CVD, PECVD, ALD, or PVD, to name a few examples. In some embodiments, gate electrode 904 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 904 may include, for instance, a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates.

Gate cap 906 may be formed by first recessing gate electrode 904 and filling the recess with a dielectric material. The dielectric material may then be polished such that its top surface is substantially coplanar with a top surface of spacer structures 404 and dielectric fill 706.

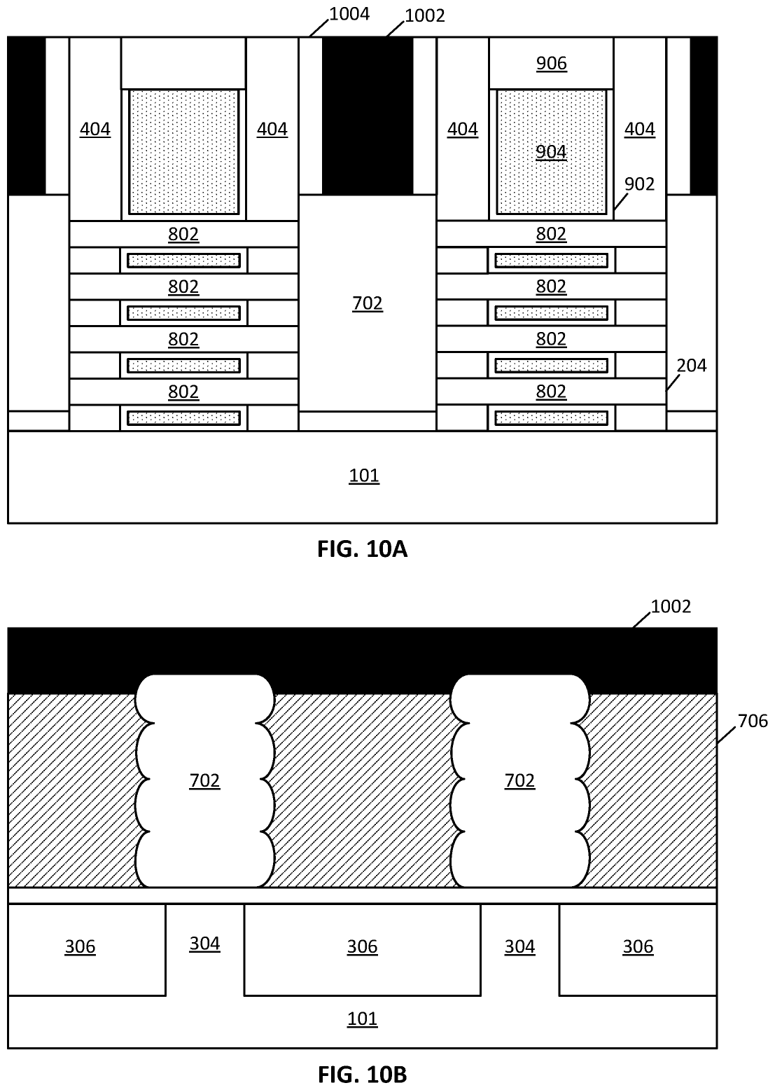

FIGS. 10A and 10B depict cross-section views of the structure shown in FIGS. 9A and 9B, respectively, following the formation of conductive contacts 1002 within the source/drain trench and on any number of source or drain regions 702, according to some embodiments. Contacts 1002 may include any suitable conductive material, such as tungsten, molybdenum, or ruthenium, for making electrical contact with the underlying source or drain regions 702. As seen in the cross section of FIG. 10B, a portion of dielectric fill 706 is recessed to expose at least the top surfaces of source or drain regions 702 and contact 1002 is formed within the recess using any suitable metal deposition process. According to some embodiments, conductive contact 1002 includes one or more silicide layers directly on the exposed surface of source or drain regions 702. In some examples, additional sidewall spacers 1004 are formed within the source/drain trench prior to the formation of contacts 1002. Sidewalls spacers 1004 may have the same material composition as spacer structures 404, or may include any other suitable dielectric material.

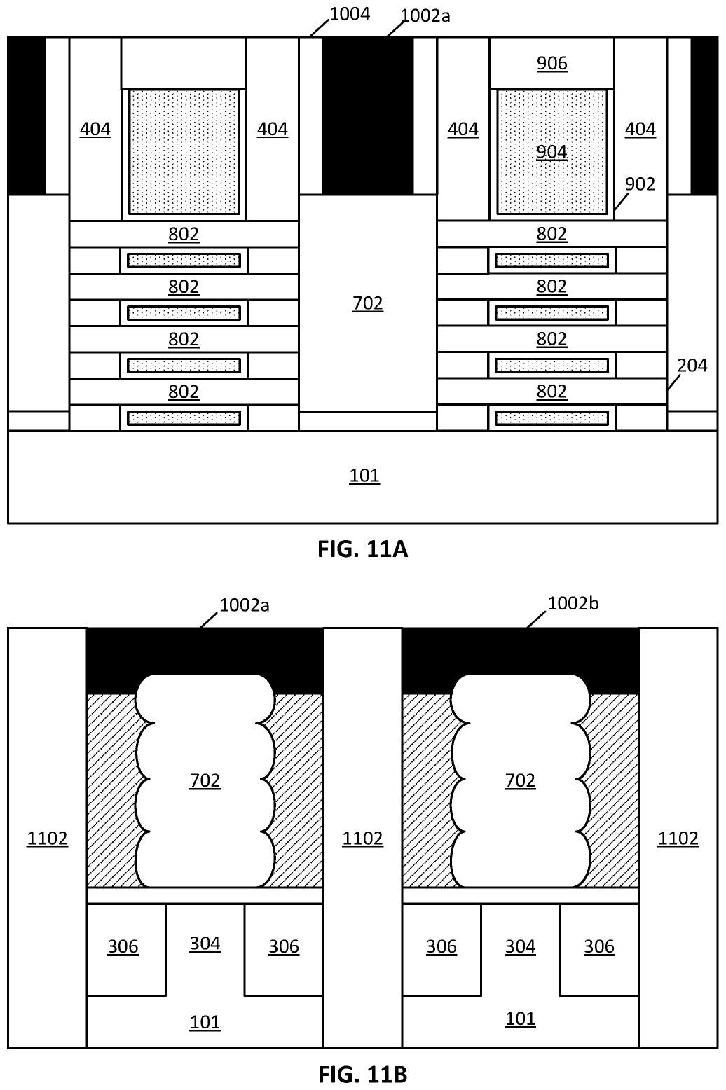

FIGS. 11A and 11B depict cross-section views of the structure shown in FIGS. 10A and 10B, respectively, following the formation of dielectric walls 1102 extending in the first direction between devices, according to some embodiments. Dielectric walls 1102 extend to a depth at least through an entire thickness of the gate structures to isolate separate gate structures along the second direction. In some embodiments, dielectric walls 1102 extend into at least a portion of dielectric fill 306 or through an entire thickness of dielectric fill 306. In some embodiments, dielectric walls 1102 extend entirely through dielectric fill 306 and into a portion of substrate 102.

According to some embodiments, dielectric walls 1102 may be formed by first forming corresponding gate cut recesses through gate cap 906, contact 1002 and gate electrode 904 using any suitable metal gate etch process that iteratively etches through portions of the gate electrode while simultaneously protecting the sidewalls of the recess from lateral etching to provide a high height-to-width aspect ratio recess (e.g., aspect ratio of 5:1 or higher, or 10:1 or higher). As shown in FIG. 9B, the gate cut recesses extend in the first direction through multiple gate trenches and source/drain trenches to isolate adjacent gate structures and source or drain regions. The gate cut recesses may be filled with one or more dielectric materials to form dielectric walls 1102. For example, dielectric walls 1102 may include only silicon oxide or silicon nitride or silicon carbide. In some examples, dielectric walls 1102 include a first dielectric layer deposited first and a second dielectric layer or dielectric fill formed on the first dielectric layer. The first dielectric layer may include a high-k dielectric material (e.g., materials with a dielectric constant higher than that of silicon oxide or higher than 3.9) while the second dielectric layer may include a low-k dielectric material (e.g. materials with a dielectric constant equal to or lower than that of silicon oxide, such as porous silicon oxide, or equal to or lower than 3.9). In the illustrated example, dielectric wall 1102 separates contact 1002 into a first contact 1002a and a second contact 1002b. In some examples where devices are closely packed, dielectric wall 1102 may contact one or more sidewalls of source or drain regions 702.

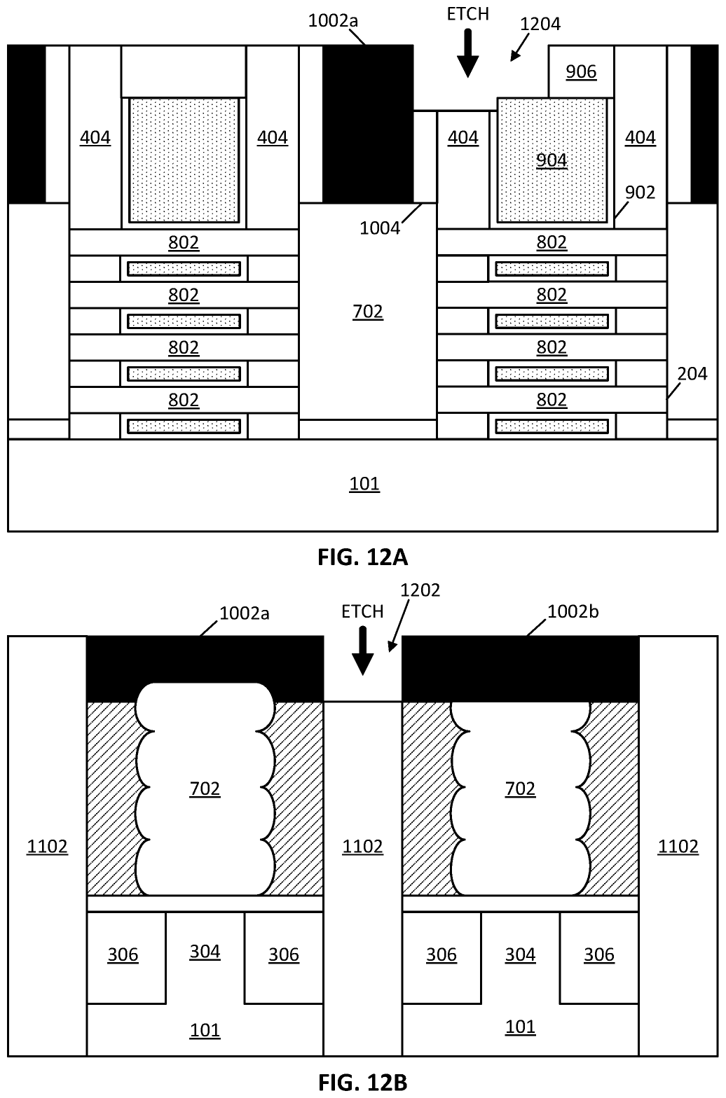

FIGS. 12A and 12B depict cross-section views of the structure shown in FIGS. 11A and 11B, respectively, following the formation of a first recess 1202 through a portion of dielectric wall 1102 and a second recess 1204 through a portion of gate cap 906 and spacer structure 404, according to some embodiments. A single masking layer may be used to expose both a portion of dielectric wall 1102 between first contact 1002a and second contact 1002b and a portion of gate cap 906 and spacer structure 404 between first contact 1002a and gate electrode 904. In this way, the same etching process may be used to form both first recess 1202 and second recess 1204 simultaneously. In some embodiments, any number of etching processes may be used to form either recess before the other, or to remove various other dielectric materials from within either or both recesses. In the illustrated example, only a portion of gate cap 906 along the first direction is removed when forming second recess 1204, while in other examples an entirety of gate cap 906 is removed along the first direction when forming second recess 1204. In some embodiments, a portion of first contact 1002a and/or a portion of gate electrode 904 is also removed when forming second recess 1204.

Each of first recess 1202 and second recess 1204 may have substantially the same depth. Second recess 1204 may have a depth that is at least enough to expose a top surface of gate electrode 904. In some examples, a portion of sidewall spacer 1004 between first contact 1002a and gate electrode 904 is also removed as part of second recess 1204. The etching process may be a dry dielectric etching procedure, such as for etching silicon nitride, that etches little to none of the conductive materials present in contacts 1002a/1002b and gate electrode 904.

FIGS. 13A and 13B depict cross-section views of the structure shown in FIGS. 12A and 12B, respectively, following the formation of a first conductive bridge 1302 within first recess 1202 and a second conductive bridge 1304 within second recess 1204, according to some embodiments. First conductive bridge 1302 extends between first contact 1002a and second contact 1002b along the second direction while second conductive bridge 1304 extends between first contact 1002a and gate electrode 904 along the first direction. Each of first conductive bridge 1302 and second conductive bridge 1304 may include any suitable conductive material, such as tungsten, molybdenum, or other metals. In some examples, first conductive bridge 1302 includes the same conductive material as first contact 1002a and second contact 1002b. In some examples, second conductive bridge 1304 includes the same conductive material as first contact 1002a and gate electrode 904. According to some embodiments, first conductive bridge 1302 and second conductive bridge 1304 are formed together such that they include the same conductive material. The conductive material of first conductive bridge 1302 and second conductive bridge 1304 may be different from the conductive material of first contact 1002a and second contact 1002b.

First contact 1002a, second contact 1002b, first conductive bridge 1302, and second conductive bridge 1304 may collectively form a single conductive contact within the device layer that contacts multiple source or drain regions 702 and at least one gate electrode 904. Additional adjacent source or drain regions 702 may also be contacted by forming additional conductive bridges across adjacent dielectric walls 1102. In some embodiments, there may not be any noticeable seams or boundaries between any of first contact 1002a, second contact 1002b, first conductive bridge 1302, or second conductive bridge 1304 depending on the materials used. When different materials or deposition processes are used, seams or boundaries may be noticeable between different conductive elements. In any such example cases, the resulting conductive contact may be referred to herein as a bridging contact structure.

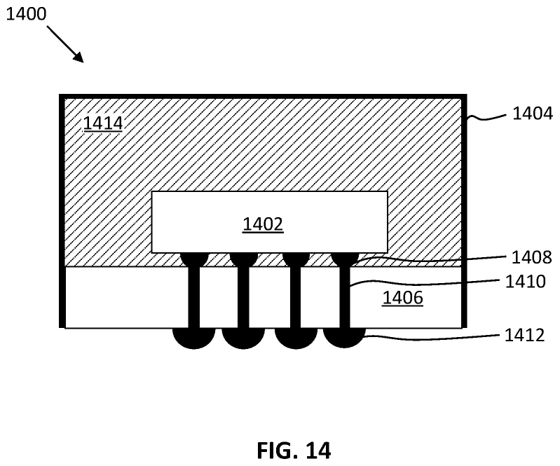

FIG. 14 illustrates an example embodiment of a chip package 1400, in accordance with an embodiment of the present disclosure. As can be seen, chip package 1400 includes one or more dies 1402. One or more dies 1402 may include at least one integrated circuit having semiconductor devices, such as any of the semiconductor devices disclosed herein. One or more dies 1402 may include any other circuitry used to interface with other devices formed on the dies, or other devices connected to chip package 1400, in some example configurations.

As can be further seen, chip package 1400 includes a housing 1404 that is bonded to a package substrate 1406. The housing 1404 may be any standard or proprietary housing, and may provide, for example, electromagnetic shielding and environmental protection for the components of chip package 1400. The one or more dies 1402 may be conductively coupled to a package substrate 1406 using connections 1408, which may be implemented with any number of standard or proprietary connection mechanisms, such as solder bumps, ball grid array (BGA), pins, or wire bonds, to name a few examples. Package substrate 1406 may be any standard or proprietary package substrate, but in some cases includes a dielectric material having conductive pathways (e.g., including conductive vias and lines) extending through the dielectric material between the faces of package substrate 1406, or between different locations on each face. In some embodiments, package substrate 1406 may have a thickness less than 1 millimeter (e.g., between 0.1 millimeters and 0.5 millimeters), although any number of package geometries can be used. Additional conductive contacts 1412 may be disposed at an opposite face of package substrate 1406 for conductively contacting, for instance, a printed circuit board (PCB). One or more vias 1410 extend through a thickness of package substrate 1406 to provide conductive pathways between one or more of connections 1408 to one or more of contacts 1412. Vias 1410 are illustrated as single straight columns through package substrate 1406 for ease of illustration, although other configurations can be used (e.g., damascene, dual damascene, through-silicon via, or an interconnect structure that meanders through the thickness of substrate 1406 to contact one or more intermediate locations therein). In still other embodiments, vias 1410 are fabricated by multiple smaller stacked vias, or are staggered at different locations across package substrate 1406. In the illustrated embodiment, contacts 1412 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1412, to inhibit shorting.

In some embodiments, a mold material 1414 may be disposed around the one or more dies 1402 included within housing 1404 (e.g., between dies 1402 and package substrate 1406 as an underfill material, as well as between dies 1402 and housing 1404 as an overfill material). Although the dimensions and qualities of the mold material 1414 can vary from one embodiment to the next, in some embodiments, a thickness of mold material 1414 is less than 1 millimeter. Example materials that may be used for mold material 1414 include epoxy mold materials, as suitable. In some cases, the mold material 1414 is thermally conductive, in addition to being electrically insulating.

### Methodology

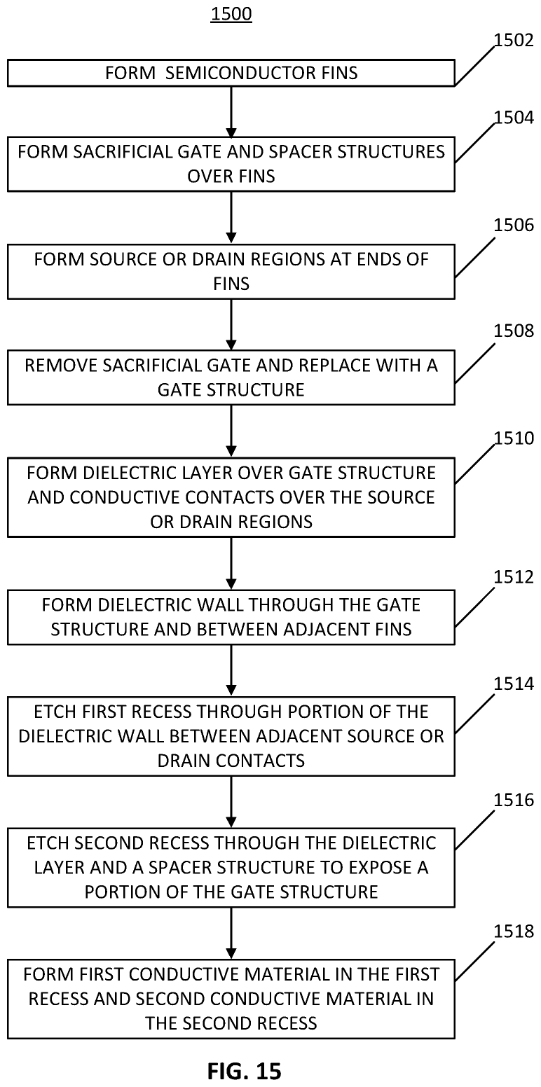

FIG. 15 is a flow chart of a method 1500 for forming at least a portion of an integrated circuit, according to an embodiment. Various operations of method 1500 may be illustrated in FIGS. 2A-13A and 2B-13B. However, the correlation of the various operations of method 1500 to the specific components illustrated in the aforementioned figures is not intended to imply any structural and/or use limitations. Rather, the aforementioned figures provide one example embodiment of method 1500. Other operations may be performed before, during, or after any of the operations of method 1500. For example, method 1500 does not explicitly describe various standard processes that are usually performed to form transistor structures. Some of the operations of method 1500 may be performed in a different order than the illustrated order.

Method 1500 begins with operation 1502 where a plurality of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. Again, the alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

Method 1500 continues with operation 1504 where sacrificial gates are formed over the fins. The sacrificial gates may be patterned using gate masking layers in strips that run orthogonally over the fins and parallel to one another (e.g., forming a cross-hatch pattern). The gate masking layers may be any suitable hard mask material, such as CHM or silicon nitride. The sacrificial gates themselves may be formed from any suitable material that can be selectively removed at a later time without damaging the semiconductor material of the fins. In one example, the sacrificial gates include polysilicon.

According to some embodiments, spacer structures are also formed on sidewalls of at least the sacrificial gates. The spacer structures may be deposited and then etched back such that the spacer structures remain mostly only on sidewalls of any exposed structures. In some cases, spacer structures may also be formed along sidewalls of the exposed fins running orthogonally between the strips of sacrificial gates. According to some embodiments, the spacer structures may be any suitable dielectric material, such as silicon nitride or silicon oxynitride.

Method 1500 continues with operation 1506 where source or drain regions are formed at opposite ends of the fins. Any exposed portions of the fins not covered by the sacrificial gates or spacer structures may be removed using any anisotropic etching process, such as reactive ion etching (RIE). Once the exposed fins have been removed, the source or drain regions may be formed in the areas that had been previously occupied by the exposed fins between the spacer structures. According to some embodiments, the source or drain regions are epitaxially grown from the exposed semiconductor material of the fins (or nanoribbons, nanowires or nanosheets, as the case may be) along the exterior walls of the spacer structures. In some example embodiments, the source or drain regions are NMOS source or drain regions (e.g., epitaxial silicon) or PMOS source or drain regions (e.g., epitaxial SiGe). A dielectric fill may formed between and over the source or drain regions along a given source/drain trench. The dielectric fill may be any suitable dielectric material, such as silicon oxide. In some examples, the dielectric fill extends over the source or drain regions up to and planar with a top surface of the spacer structures. The dielectric fill also acts as an electrical insulator between adjacent source or drain regions, although some adjacent source or drain regions may have merged together during their growth.

Method 1500 continues with operation 1508 where gate structures are formed over the semiconductor material of the various semiconductor fins. The sacrificial gates are first removed along with any sacrificial layers within the exposed fins between the spacer structures (in the case of GAA structures). The gate structures may then be formed in place of the sacrificial gates. The gate structures may each include both a gate dielectric and a gate electrode. The gate dielectric is first formed over the exposed semiconductor regions between the spacer structures followed by forming the gate electrode within the remainder of the trench between the spacer structures, according to some embodiments. The gate dielectric may include any number of dielectric layers deposited using a CVD process, such as ALD. The gate electrode can include any conductive material, such as a metal, metal alloy, or polysilicon. The gate electrode may be deposited using electroplating, electroless plating, CVD, ALD, PECVD, or PVD, to name a few examples.

Method 1500 continues with operation 1510 where a dielectric cap layer is formed over the gate structure and conductive contacts are formed over the source or drain regions along the source/drain trench. According to some embodiments, the gate electrode may be recessed below a top surface of the spacer structures and the dielectric cap layer is formed within the recess. In some examples, the dielectric cap layer is polished such that a top surface of the dielectric cap layer is substantially coplanar with a top surface of the spacer structures. The dielectric cap layer may include any suitable dielectric material, such as silicon nitride, or the same dielectric material as the spacer structures.

According to some embodiments, the dielectric fill within the source/drain trench may be recessed at least until a top surface of the source or drain regions in the trench are exposed. A conductive contact may be formed within the recess in the source/drain trench such that the conductive contact touches the top surface of one or more source or drain regions in the trench. In some other examples, separate conductive contacts may be formed within the trench over corresponding source or drain regions. The conductive contacts may include any suitable conductive material, such as tungsten, molybdenum, ruthenium, or cobalt.

Method 1500 continues with operation 1512 where dielectric walls are formed through the gate structure between adjacent pairs of fins. According to some embodiments, trenches are etched through both the gate structures and through the dielectric fill around the source or drain regions. The trenches may extend substantially parallel with one another and lengthwise in the same direction as the length of the fins or nanowires. A single etching process may be used to form all of the trenches through a mask with a grating pattern. A reactive ion etching (RIE) process may be used to cut through the various material layers and form the trenches. Due to the use of a single mask pattern to form the trenches, any alignment registration errors will be consistent across the integrated circuit, according to some embodiments. The trenches are filled with a dielectric material to form the parallel dielectric walls through the integrated circuit. The trenches may be filled with any suitable low-K dielectric material, such as silicon nitride. In some embodiments, each pair of semiconductor devices includes a dielectric wall between them. Furthermore, the dielectric walls extend between the gate structures and between the source or drain regions of adjacent devices.

Method 1500 continues with operation 1514 where a first recess is etched through a portion of a given dielectric wall between adjacent source or drain contacts. According to some embodiments, the first recess is etched through a portion of the dielectric wall within the source/drain trench. An entire width of the dielectric wall along the second direction may be removed such that the first recess exposes sidewall portions of each conductive contact on either side of the dielectric wall. The depth of the first recess may vary depending on the application but may be between about 5 nm and about 30 nm. Any suitable dielectric etching process may be used to remove a portion of the dielectric wall.

Method 1500 continues with operation 1516 where a second recess is etched through a portion of the dielectric cap layer and adjacent spacer structure to expose at least a portion of the gate electrode beneath the dielectric cap layer. According to some embodiments, the second recess also exposes a sidewall portion of an adjacent conductive contact. The second recess may extend in the first direction from the conductive contact to the gate electrode. In some embodiments, a portion of the adjacent conductive contact is also removed such that the second recess extends into a portion of the conductive contact. The depth of the second recess may vary depending on the application but may be between about 5 nm and about 30 nm. Any suitable dielectric etching process may be used to remove the portion of the spacer structure and dielectric cap layer. In some embodiments, the first and second recesses expose sidewall portions of the same conductive contact. Operations 1514 and 1516 may be performed simultaneously by the same etching process.

Method 1500 continues with operation 1518 where a first conductive bridge is formed in the first recess and a second conductive bridge is formed in the second recess. Any suitable metal deposition process may be used to form the first and second conductive bridges. Each of the first conductive bridge and the second conductive bridge may include any suitable conductive material, such as tungsten, molybdenum, ruthenium, or other metals. In some examples, the first conductive bridge includes the same conductive material as either conductive contact that it touches. In some examples, the second conductive bridge includes the same conductive material as the gate electrode or the conductive contact that it touches. According to some embodiments, the first conductive bridge and the second conductive bridge are formed together such that they include the same conductive material. The conductive material of the first conductive bridge and the second conductive bridge may be different from the conductive material of any of the conductive contacts.

### Example System

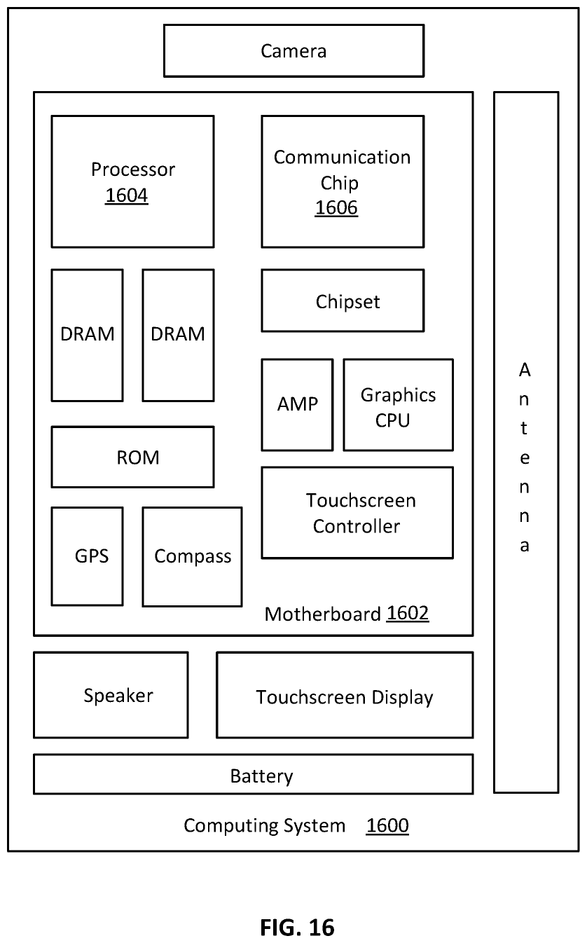

FIG. 16 is an example computing system implemented with one or more of the integrated circuit structures as disclosed herein, in accordance with some embodiments of the present disclosure. As can be seen, the computing system 1600 houses a motherboard 1602. The motherboard 1602 may include a number of components, including, but not limited to, a processor 1604 and at least one communication chip 1606, each of which can be physically and electrically coupled to the motherboard 1602, or otherwise integrated therein. As will be appreciated, the motherboard 1602 may be, for example, any printed circuit board (PCB), whether a main board, a daughterboard mounted on a main board, or the only board of system 1600, etc.

Depending on its applications, computing system 1600 may include one or more other components that may or may not be physically and electrically coupled to the motherboard 1602. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1600 may include one or more integrated circuit structures or devices configured in accordance with an example embodiment (e.g., a module including an integrated circuit device on a substrate, the substrate having one or more semiconductor devices that include a bridging contact structure that bridges between source/drain contacts and to an adjacent gate electrode, as variously provided herein). In some embodiments, multiple functions can be integrated into one or more chips (e.g., for instance, note that the communication chip 1606 can be part of or otherwise integrated into the processor 1604).

The communication chip 1606 enables wireless communications for the transfer of data to and from the computing system 1600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1606 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1600 may include a plurality of communication chips 1606. For instance, a first communication chip 1606 may be dedicated to shorter range wireless communications such as Wi-Fi and Bluetooth and a second communication chip 1606 may be dedicated to longer range wireless communications such as GPS, EDGE, GPRS, CDMA, WiMAX, LTE, Ev-DO, and others.

The processor 1604 of the computing system 1600 includes an integrated circuit die packaged within the processor 1604. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1606 also may include an integrated circuit die packaged within the communication chip 1606. In accordance with some such example embodiments, the integrated circuit die of the communication chip includes one or more semiconductor devices as variously described herein. As will be appreciated in light of this disclosure, note that multi-standard wireless capability may be integrated directly into the processor 1604 (e.g., where functionality of any chips 1606 is integrated into processor 1604, rather than having separate communication chips). Further note that processor 1604 may be a chip set having such wireless capability. In short, any number of processor 1604 and/or communication chips 1606 can be used. Likewise, any one chip or chip set can have multiple functions integrated therein.

In various implementations, the computing system 1600 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1600 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a first semiconductor device having a first semiconductor region extending in a first direction from a first source or drain region, and a first gate structure extending in a second direction over the first semiconductor region, and a second semiconductor device having a second semiconductor region extending in the first direction from a second source or drain region, and a second gate structure extending in the second direction over the second semiconductor region. The integrated circuit further includes a dielectric wall extending in the first direction between the first gate structure and the second gate structure and between the first source or drain region and the second source or drain region, and a conductive contact having a first region on a top surface of the first source or drain region, a second region that extends through a portion of the dielectric wall along the second direction, a third region on a top surface of the second source or drain region, and a fourth region on a top surface of the first gate structure.

Example 2 includes the integrated circuit of Example 1, wherein the first semiconductor region and the second semiconductor region comprise a plurality of semiconductor nanoribbons.

Example 3 includes the integrated circuit of Example 2, wherein the plurality of semiconductor nanoribbons comprise germanium, silicon, or a combination thereof.

Example 4 includes the integrated circuit of any one of Examples 1-3, wherein a top surface of each of the first region, second region, third region, and fourth region of the conductive contact are substantially coplanar.

Example 5 includes the integrated circuit of any one of Examples 1-4, wherein the first region and the third region comprise a first conductive material, and the second region and the fourth region comprise a second conductive material different from the first conductive material.

Example 6 includes the integrated circuit of Example 5, wherein the first conductive material comprises tungsten and the second conductive material comprises molybdenum.

Example 7 includes the integrated circuit of any one of Examples 1-6, wherein the first region, second region, third region, and fourth region of the conductive contact comprise a same conductive material.

Example 8 includes the integrated circuit of any one of Examples 1-7, wherein the fourth region of the conductive contact extends away from the first region of the conductive contact along the first direction.

Example 9 is a printed circuit board comprising the integrated circuit of any one of Examples 1-8.

Example 10 is an electronic device that includes a chip package comprising one or more dies. At least one of the one or more dies includes a first semiconductor device having a first semiconductor region extending in a first direction from a first source or drain region, and a first gate structure extending in a second direction over the first semiconductor region, a second semiconductor device having a second semiconductor region extending in the first direction from a second source or drain region, and a second gate structure extending in the second direction over the second semiconductor region, a gate cut extending in the first direction between the first gate structure and the second gate structure and between the first source or drain region and the second source or drain region, and a conductive contact. The conductive contact has a first region on a top surface of the first source or drain region, a second region that extends through a portion of the gate cut along the second direction, a third region on a top surface of the second source or drain region, and a fourth region on a top surface of the first gate structure.

Example 11 includes the electronic device of Example 10, wherein the first semiconductor region and the second semiconductor region comprise a plurality of semiconductor nanoribbons.

Example 12 includes the electronic device of Example 10 or 11, wherein respective top surfaces of the first region, second region, third region, and fourth region of the conductive contact are substantially coplanar.

Example 13 includes the electronic device of any one of Examples 10-12, wherein respective top surfaces of the first region, second region, third region, and fourth region of the conductive contact are substantially coplanar, and below a first interconnect layer.

Example 14 includes the electronic device of any one of Examples 10-13, wherein the first region and the third region comprise a first conductive material, and the second region and the fourth region comprise a second conductive material different from the first conductive material.

Example 15 includes the electronic device of Example 14, wherein the first conductive material comprises tungsten and the second conductive material comprises molybdenum.

Example 16 includes the electronic device of any one of Examples 10-15, wherein the first region, second region, third region, and fourth region of the conductive contact comprise a same conductive material.

Example 17 includes the electronic device of any one of Examples 10-16, wherein the fourth region of the conductive contact extends away from the first region of the conductive contact along the first direction.

Example 18 includes the electronic device of any one of Examples 10-17, further comprising a printed circuit board, wherein the chip package is coupled to the printed circuit board.

Example 19 is a method of forming an integrated circuit. The method includes forming a first fin comprising first semiconductor material and a second fin comprising second semiconductor material, the first and second fins extending above a substrate and each extending in a first direction; forming a gate electrode extending over the first fin and the second fin in a second direction different from the first direction; forming a dielectric layer over the gate electrode; forming a first source or drain region at one end of the first fin and a second source or drain region at one end of the second fin; forming a recess through the gate electrode between the first fin and the second fin, the recess further extending in the first direction between the first source region and the second source region; forming a dielectric material within the recess; forming a first conductive contact on the first source or drain region and a second conductive contact on the second source or drain region; recessing a portion of the dielectric material between the first conductive contact and the second conductive contact to form a first recess; recessing at least a portion of the dielectric layer to expose at least a portion of the gate electrode and to form a second recess; and forming first conductive material within the first recess and second conductive material within the second recess, such that the first conductive material contacts the first conductive contact and the second conductive contact and the second conductive material contacts the first conductive contact.

Example 20 includes the method of Example 19, wherein recessing at least a portion of the dielectric layer further comprises recessing at least a portion of a dielectric spacer between the dielectric layer and the first conductive contact.

Example 21 includes the method of Example 19 or 20, further comprising polishing a top surface of the first conductive contact, the second conductive contact, first conductive material, and second conductive material using chemical mechanical polishing (CMP).

Example 22 includes the method of any one of Examples 19-21, wherein recessing the portion of the dielectric material and recessing at least a portion of the dielectric layer occur simultaneously during a single recessing operation.

Example 23 includes the method of Example 22, wherein the single recessing operation further comprises recessing at least a portion of the first conductive contact.

Example 24 is an integrated circuit that includes a first semiconductor device having a first semiconductor region extending in a first direction from a first source or drain region, and a first gate structure extending in a second direction over the first semiconductor region, and a second semiconductor device having a second semiconductor region extending in the first direction from a second source or drain region, and a second gate structure extending in the second direction over the second semiconductor region. The integrated circuit further includes a dielectric wall extending in the first direction between the first gate structure and the second gate structure and between the first source or drain region and the second source or drain region, a first conductive structure on a top surface of the first source or drain region, a second conductive structure on a top surface of the second source or drain region, a third conductive structure extending between the first conductive structure and the second conductive structure, and a fourth conductive structure extending from the first conductive structure and on a top surface of the first gate structure.

Example 25 includes the integrated circuit of Example 24, wherein the first semiconductor region and the second semiconductor region comprise a plurality of semiconductor nanoribbons.

Example 26 includes the integrated circuit of Example 24 or 25, wherein the first semiconductor device, second semiconductor device, first conductive structure, second conductive structure, third conductive structure, and fourth conductive structure are part of a device layer that is below an interconnect structure that includes one or more interconnect layers.

Example 27 includes the integrated circuit of any one of Examples 24-26, wherein the third conductive structure extends through the dielectric wall between the first conductive structure and the second conductive structure.

Example 28 includes the integrated circuit of any one of Examples 24-27, wherein respective top surfaces of the first conductive structure, second conductive structure, third conductive structure, and fourth conductive structure are substantially coplanar.

Example 29 includes the integrated circuit of any one of Examples 24-28, wherein the first conductive structure and the second conductive structure comprise a first conductive material, and the third conductive structure and the fourth conductive structure comprise a second conductive material different from the first conductive material.

Example 30 includes the integrated circuit of Example 29, wherein the first conductive material comprises tungsten and the second conductive material comprises molybdenum.

Example 31 includes the integrated circuit of any one of Examples 24-28, wherein each of the first conductive structure, second conductive structure, third conductive structure, and fourth conductive structure comprise a same conductive material.

Example 32 includes the integrated circuit of any one of Examples 24-31, wherein the fourth conductive structure extends away from the first conductive structure along the first direction.

Example 33 is a printed circuit board comprising the integrated circuit of any one of Examples 24-32.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor device having a first semiconductor region extending in a first direction from a first source or drain region, and a first gate structure extending in a second direction over the first semiconductor region;
a second semiconductor device having a second semiconductor region extending in the first direction from a second source or drain region, and a second gate structure extending in the second direction over the second semiconductor region;
a dielectric wall extending in the first direction between the first gate structure and the second gate structure and between the first source or drain region and the second source or drain region; and
a conductive contact having a first region on a top surface of the first source or drain region, a second region that extends through a portion of the dielectric wall along the second direction, a third region on a top surface of the second source or drain region, and a fourth region on a top surface of the first gate structure.

2. The integrated circuit of claim 1, wherein the first semiconductor region and the second semiconductor region comprise a plurality of semiconductor nanoribbons.

3. The integrated circuit of claim 1, wherein a top surface of each of the first region, second region, third region, and fourth region of the conductive contact are substantially coplanar.

4. The integrated circuit of claim 1, wherein the first region and the third region comprise a first conductive material, and the second region and the fourth region comprise a second conductive material different from the first conductive material.

5. The integrated circuit of claim 1, wherein the first region, second region, third region, and fourth region of the conductive contact comprise a same conductive material.

6. The integrated circuit of claim 1, wherein the fourth region of the conductive contact extends away from the first region of the conductive contact along the first direction.

7. A printed circuit board comprising the integrated circuit of claim 1.

8. An electronic device, comprising:
a chip package comprising one or more dies, at least one of the one or more dies comprising a first semiconductor device having a first semiconductor region extending in a first direction from a first source or drain region, and a first gate structure extending in a second direction over the first semiconductor region;
a second semiconductor device having a second semiconductor region extending in the first direction from a second source or drain region, and a second gate structure extending in the second direction over the second semiconductor region;
a gate cut extending in the first direction between the first gate structure and the second gate structure and between the first source or drain region and the second source or drain region; and
a conductive contact having a first region on a top surface of the first source or drain region, a second region that extends through a portion of the gate cut along the second direction, a third region on a top surface of the second source or drain region, and a fourth region on a top surface of the first gate structure.

9. The electronic device of claim 8, wherein respective top surfaces of the first region, second region, third region, and fourth region of the conductive contact are substantially coplanar, and below a first interconnect layer.

10. The electronic device of claim 8, wherein the first region and the third region comprise a first conductive material, and the second region and the fourth region comprise a second conductive material different from the first conductive material.

11. The electronic device of claim 10, wherein the first conductive material comprises tungsten and the second conductive material comprises molybdenum.

12. The electronic device of claim 8, wherein the first region, second region, third region, and fourth region of the conductive contact comprise a same conductive material.

13. The electronic device of claim 8, wherein the fourth region of the conductive contact extends away from the first region of the conductive contact along the first direction.

14. An integrated circuit comprising:
a first semiconductor device having a first semiconductor region extending in a first direction from a first source or drain region, and a first gate structure extending in a second direction over the first semiconductor region;
a second semiconductor device having a second semiconductor region extending in the first direction from a second source or drain region, and a second gate structure extending in the second direction over the second semiconductor region;
a dielectric wall extending in the first direction between the first gate structure and the second gate structure and between the first source or drain region and the second source or drain region;
a first conductive structure on a top surface of the first source or drain region;
a second conductive structure on a top surface of the second source or drain region;
a third conductive structure extending between the first conductive structure and the second conductive structure; and
a fourth conductive structure extending from the first conductive structure and on a top surface of the first gate structure.

15. The integrated circuit of claim 14, wherein the first semiconductor device, second semiconductor device, first conductive structure, second conductive structure, third conductive structure, and fourth conductive structure are part of a device layer that is below an interconnect structure that includes one or more interconnect layers.

16. The integrated circuit of claim 14, wherein the third conductive structure extends through the dielectric wall between the first conductive structure and the second conductive structure.

17. The integrated circuit of claim 14, wherein respective top surfaces of the first conductive structure, second conductive structure, third conductive structure, and fourth conductive structure are substantially coplanar.

18. The integrated circuit of claim 14, wherein the first conductive structure and the second conductive structure comprise a first conductive material, and the third conductive structure and the fourth conductive structure comprise a second conductive material different from the first conductive material.

19. The integrated circuit of claim 14, wherein each of the first conductive structure, second conductive structure, third conductive structure, and fourth conductive structure comprise a same conductive material.

20. The integrated circuit of claim 14, wherein the fourth conductive structure extends away from the first conductive structure along the first direction.
